(19) United States
(12) Patent Application Publication
(10) Pub. No.: US 2007/0279715 A1
(43) Pub. Date: Dec. 6, 2007

(54) Color conversion definition creating apparatus, and color conversion definition creating program storage medium

(75) Inventor: Seiichiro Morikawa, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, MINATO-KU (JP)

(21) Appl. No.: 11/798,354

(22) Filed: May 14, 2007

(30) Foreign Application Priority Data
May 31, 2006 (JP) 2006-151994

(51) Int. Cl. G03F 3/08; G09G 5/02

(52) U.S. Cl. 358/518; 345/589

(57) ABSTRACT

A color conversion definition creating apparatus is capable of creating a color conversion definition that defines a color conversion from a three-dimensional color space to a four or more-dimensional color space with greater accuracy. The color conversion definition creating apparatus comprises the reference definition obtaining section, the range computing section, the correspondence function obtaining section, the component determination section, and the correspondence computing section.

### BACKGROUND OF THE INVENTION

1. Field of the Invention

The present invention relates to a color conversion definition creating apparatus for creating a color conversion definition that defines a color conversion from a first color space having three coordinate axes to a second color space having four or more coordinate axes, and a color conversion definition creating program storage medium storing a color conversion definition creating program which causes a computer to operate as such a color conversion definition creating apparatus, when the color conversion definition creating program is incorporated into the computer and is executed.

2. Description of the Related Art

There are known various types of input devices for deriving image data upon receipt of an image, for example, a color scanner for deriving image data upon reading of a recorded image, and a digital still camera (DSC) for deriving image data by means of reading through formation of an image of the subject on a solid state imaging device. According to those input devices, there is obtained image data in which a color of an image is represented by a combination of component values of three colors for example of R (red), G (green) and B (blue). Here, a color space (for example, RGB color space) having coordinate axes associated with individual component values, which represents the association between the component value and the color in the image data, depends on equipment characteristic of the input device involved in the image data.

Also with respect to an output device for outputting an image in accordance with image data, there are known various types of output devices, for example, a photographic printer for recording an image on a photographic paper in such a manner that the photographic paper is exposed with a laser light and the exposed photographic paper is developed, a printer for recording an image on a paper in accordance with an electrophotographic system and an ink jet system, a printing machine for creating a large amount of printed matters through running a rotary press, and an image display unit for displaying an image on a display screen in accordance with image data, for example, a CRT display and a plasma display. Those output devices output an image including colors in accordance with image data in which a color of an image is represented by for example, a combination of component values of three colors of R (red), G (green) and B (blue), or a combination of component values of four colors of C (cyan), M (magenta), Y (yellow), and K (black). Here, a color space (for example, RGB color space, or CMYK color space) having coordinate axes associated with individual component values, which represents the association between the component value and the color in the image data to be treated by the output device, depends on equipment characteristic of the output device that outputs an image in accordance with the image data.

In general, the color space corresponding to the handled image data is mutually different in the input device and the output device. Therefore, when the image is output with the output device by using the image data of (R,G,B)=(50,100,200) obtained with the input device as it is for instance even if both the input device and the output device are devices that treat the image data where the color of the image is expressed by combining the component values of the RGB 3 colors, the color of the image that is an origin input with the input device does not correspond to the color of the image output with the output device in general. Therefore, when it is intended to obtain image data through reading the original with the input device, and to reproduce the original with the output device based on the image data, the image data obtained with the input device is not sent to the output device as it is but it is necessary to convert the image data between those. Conversion that pays attention to the color of the image is done here, and the conversion of the image data is referred to as a color conversion. Moreover, LUT (look-up table) and the like, which define the interrelation of the image data between before and after the color conversion, is referred to as a color conversion definition.

For instance, when an image that is represented by image data where a color is expressed by the RGB color space obtained with a certain input device is output with an output device where a color is expressed with a color material of the CMYK 4 colors, there is used the color conversion definition that defines the color conversion from the RGB color space that depends on the input device into the CMYK color space that depends to the output device. And, the image data where the color is expressed by the RGB color space is converted into the image data where the color is expressed by the CMYK color space by the color conversion that uses the color conversion definition.

Here, such a color conversion is usually done to the device like the Lab color space and the XYZ color space for instance through a common color space of non-dependence. Therefore, the above-mentioned color conversion definition is strictly one in which the color conversion definition on the input side where the color conversion from the color space that depends on the input device into a common color space is defined is coupled with the color conversion definition on the output side where the color conversion from a common color space into the color space that depends on the output device.

In the output device such as printers and printing machines, it is often happed that CMYK 4 colors ink is used as a color material. Such an output device corresponds to the four-dimensional color space of CMYK color space. Here, because a common color space is usually a three-dimensional color space such as the Lab color space and the XYZ color space, the color conversion definition of such an output device on the output side becomes the one to define the color conversion from the three-dimensional color space to the four-dimensional color space. Here, such a color conversion definition is created by computing coordinates in the four-dimensional color space corresponding to each two or more coordinates in three-dimensional color space for instance. At this time, coordinates of the four-dimensional color space corresponding to coordinates of the three-dimensional color space are not obtained in general mathematical and uniquely. Then, hitherto there is adopted a method in which coordinates in the four-dimensional color space corresponding to coordinates of the three-dimensional color space is determined by an already-known method of determining three coordinates components of the remainder for instance after one coordinates component of coordinates of the four-dimensional color space is fixed to a prescribed value.

By the way, in recent years, in the field of the print, colors (trait) other than the process color such as R color, G color and B colors have come to be used for instance in the output device such as printers and printing machines to appropriately express the color that cannot be expressed only by such a process color in addition to the CMYK 4 colors (process color). When such a trait is used, the color conversion definition on the output side is the vicinity of the one to define the color conversion from the three-dimensional color space to five or more-dimensional color space. In the already-known method that has been used to determine the color conversion definition that defines the color conversion from the three-dimensional color space to the four-dimensional color space, determining the color conversion definition when the trait is used becomes difficult.

Then, for instance, there is proposed such a technology that the total range of the color, which can be expressed with five or more colors including the trait, is divided into two or more parts expressible by four colors of the five or more colors, in the color space on the output side, and then the definition that represents the association between three dimensions and four dimensions on each part is determined by an already-known technique, and thereafter the definitions of individual parts are synthesized, so that the color conversion definition that defines the color conversion from three-dimensional color space into the five or more-dimensional color space is completed (for example, cf. Japanese patent document: Japanese Patent Application Laid Open Gazette TokuKai 2001-13640).

However, according to the technology disclosed in the above-referenced Japanese patent document it is necessary to prevent the flight and the tone jump etc. of the color in the vicinity of the boundary of the above-mentioned two or more parts of an unnatural color being especially caused in the color conversion that uses the color conversion definition obtained through the above-mentioned synthesis. Therefore, according to the technology disclosed in the above-referenced Japanese patent document, the limitation is added in the computation of coordinates on the color space on the output side corresponding to coordinates on a common color space in order to secure continuousness to the color in the above-mentioned vicinity of the boundary, and as a result, the accuracy of the color conversion is sacrificed for securing continuousness.

Though there is explained in the above the problem of low degree of accuracy about the color conversion definition that defines the color conversion from a common color space such as the Lab color space and the XYZ color space into the four or more-dimensional color space that depends on the output device, such a problem occurs on the color conversion definition that defines the color conversion from the three-dimensional color space into the four or more-dimensional color space in general.

### SUMMARY OF THE INVENTION

In view of the foregoing, it is an object of the present invention to provide a color conversion definition creating apparatus capable of creating a color conversion definition that defines a color conversion from a three-dimensional color space to a four or more-dimensional color space with greater accuracy, and a color conversion definition creating program storage medium storing a color conversion definition creating program which causes a computer to operate as such a color conversion definition creating apparatus, when the color conversion definition creating program is incorporated into the computer and is executed.

To achieve the above-mentioned object, the present invention provides a color conversion definition creating apparatus for creating a color conversion definition that defines a color conversion from a first color space having three coordinate axes to a second color space having four or more coordinate axes, the conversion definition creating apparatus comprising:

a reference definition obtaining section that obtains a reference definition defining a color conversion from the second color space to the first color space;

a range computing section that determines a starting coordinate on the first colors pace, and computes, as to coordinate components of coordinate axes other than three predetermined coordinate axes among the coordinate axes of the second color space, a component range in which mapping is permitted onto the starting coordinate by the color conversion according to the reference conversion definition;

a correspondence function obtaining section that obtains correspondence functions in which relative positions of the coordinate components within the component range are associated with individual coordinates on the first color space;

a component determination section that determines coordinate components associated with the starting coordinate in accordance with the component range computed by the range computing section and the correspondence function obtained by the correspondence function obtaining section; and

a correspondence computing section that computes individual coordinate components of said three predetermined coordinate axes in accordance with the starting coordinate, the coordinate components determined by the component determination section, and the reference definition obtained by the reference definition obtaining section, so that coordinates of the second color space associated with the starting coordinate are obtained.

According to the color conversion definition creating apparatus of the present invention, two or more coordinates (for example, coordinates of lattice points regularly arranged) on three-dimensional first color space are assumed to be the starting coordinates, and coordinates of four or more dimensional second color space associated with individual starting coordinates are determined. This feature makes it possible to create a color conversion definition defining color conversion from the three-dimensional color space to four or more dimensional color space. To determine a coordinate value of the second color space associated with a certain starting coordinate, coordinate components other than three predetermined coordinate axes are determined under a certain degree of voluntariness to be a boundary condition, and then individual coordinate components on those three predetermined coordinate axes are uniquely computed. With respect to the coordinate components other than three predetermined coordinate axes, first, there is computed a component range in which mapping is permitted onto the starting coordinate by the color conversion according to the reference conversion definition, and then the coordinate component is decided to the value within the computed component range. Therefore, with respect to this coordinates component, it is possible to avoid such a trouble that the value that lowers the accuracy of the color conversion is inadvertently determined. Moreover, this coordinates component is decided in accordance with the correspondence function. Accordingly, the use of the correspondence functions in which relative positions of the coordinate components within the component range are associated with individual coordinates on the first color space makes it possible to avoid trouble such as jump and the tone jump of an unnatural color in the color conversion. Thus, according to the color conversion definition creating apparatus of the present invention, it is possible to create the color conversion definition that defines the color conversion from the three-dimensional color space to the four or more-dimensional color space with great accuracy.

In the color conversion definition creating apparatus according to the present invention as mentioned above, it is a typical aspect that the first color space is a color space in which a color is represented by a colorimetric value.

In the color conversion definition creating apparatus according to the present invention as mentioned above, it is a typical aspect that the second color space is a color space having the coordinate axes associated with four or more color elements, respectively, which represents a color that is expressed by those color elements.

According to the above-mentioned aspects, it is possible to create a color conversion definition that defines a color conversion from a color space in which a color is represented by calorimetric values, for example, a Lab color space, and XYZ color spaces to CMYK color spaces which are typical color spaces that depend on the output device such as a printer and a printing machine.

In the color conversion definition creating apparatus according to the present invention as mentioned above, it is preferable that the second color space is five or more dimensional color space,

the component determination section determines coordinate components one by one on individual coordinate axes other than three predetermined coordinate axes, and

the range computing section computes, as to coordinate axes that are not yet decided in coordinate component, the component range under condition that as to coordinate axes that are already decided in coordinate component, the coordinate component is used on a fixing basis.

According to the color conversion definition creating apparatus of the present invention as mentioned above, even if the coordinate axes other than three predetermined coordinate axes exist two or more, coordinate components are sequentially decided as to individual coordinate axes, while the decided coordinate component is used on a fixing basis.

In the color conversion definition creating apparatus according to the present invention as mentioned above, it is preferable that the second color space is a color space having the coordinate axes associated with four or more color elements including K color, respectively, which represents a color that is expressed by those color elements, and

the range computing section and the component determination section execute computation of the component range and determination of the coordinate components as to coordinate axis associated with K color first, respectively.

In the color conversion definition creating apparatus according to the present invention as mentioned above, it is preferable that the second color space is a color space having the coordinate axes associated with five or more color elements including CMY three colors, K color, and one or more traits, respectively, which represents a color that is expressed by those color elements,

the range computing section and the component determination section execute computation of the component range and determination of the coordinate components as to coordinate axis associated with K color first, respectively, and then execute computation of the component range and determination of the coordinate components as to coordinate axes associated with individual traits, sequentially, respectively, and

the correspondence computing section computes coordinate components as to individual coordinate axes associated with CMY three colors, respectively.

According to the color conversion definition creating apparatus of the present invention as mentioned above, there are executed computation of the component range and determination of the coordinate components as to coordinate axis associated with K color first, which is easy to be recognized for person's eyes. This feature makes it possible to create the color conversion definition with great accuracy in higher degree of freedom.

To achieve the above-mentioned object, the present invention provides a color conversion definition creating program storage medium storing a color conversion definition creating program which causes a computer to operate as a color conversion definition creating apparatus, when the color conversion definition creating program is incorporated into the computer and is executed, the color conversion definition creating apparatus creating a color conversion definition that defines a color conversion from a first color space having three coordinate axes to a second color space having four or more coordinate axes, the conversion definition creating apparatus comprising:

a reference definition obtaining section that obtains a reference definition defining a color conversion from the second color space to the first color space;

a range computing section that determines a starting coordinate on the first color space, and computes, as to coordinate components of coordinate axes other than three predetermined coordinate axes among the coordinate axes of the second color space, a component range in which mapping is permitted onto the starting coordinate by the color conversion according to the reference conversion definition;

a correspondence function obtaining section that obtains correspondence functions in which relative positions of the coordinate components within the component range are associated with individual coordinates on the first color space;

a component determination section that determines coordinate components associated with the starting coordinate in accordance with the component range computed by the range computing section and the correspondence function obtained by the correspondence function obtaining section; and

a correspondence computing section that computes individual coordinate components of said three predetermined coordinate axes in accordance with the starting coordinate, the coordinate components determined by the component determination section, and the reference definition obtained by the reference definition obtaining section, so that coordinates of the second color space associated with the starting coordinate are obtained.

According to the color conversion definition creating program storage medium of the present invention, it is possible to easily implement a color conversion definition apparatus capable of creating the color conversion definition that defines the color conversion from the three-dimensional color space to the four or more-dimensional color space with great accuracy.

### BRIEF DESCRIPTION OF THE DRAWINGS

FIG. 1 is a construction view of a printing system to which an embodiment of the present invention is applied.

FIG. 2 is a block diagram useful for understanding a relation between a color conversion apparatus and a color conversion definition creating apparatus.

FIG. 3 is a perspective view of a personal computer 100 shown in FIG. 1.

FIG. 4 is a hardware structural view of the personal computer 100 shown in FIG. 1.

FIG. 5 is a view useful for understanding a color conversion definition creating program storage medium storing a color conversion definition creating program according to an embodiment of the present invention.

FIG. 6 is a block diagram of the color conversion definition creating apparatus according to an embodiment of the present invention, which is shown in FIG. 2 with a block.

FIG. 7 is a view useful for understanding a state that a component range of K value, in which a mapping can be made at a certain starting coordinate, is computed.

FIG. 8 is a view showing an example of weight function W_{KL} of L* value and an example of weight function W_{KC} of chroma saturation C.

FIG. 9 is a view useful for understanding a state that a component range of O value, in which a mapping can be made at a certain starting coordinate, is computed.

FIG. 10 is a view showing an example of weight function W_{OH} of color-phase angle H and an example of weight function W_{OC} of chroma saturation C.

FIG. 11 is a view useful for understanding a state that a component range of C value, in which a mapping can be made at a certain starting coordinate, is computed.

FIG. 12 is a view showing an example of weight function W_{CH} of color-phase angle H and an example of weight function W_{CC} of chroma saturation C.

### DETAILED DESCRIPTION OF PREFERRED EMBODIMENTS

Embodiments of the present invention will be described with reference to the accompanying drawings.

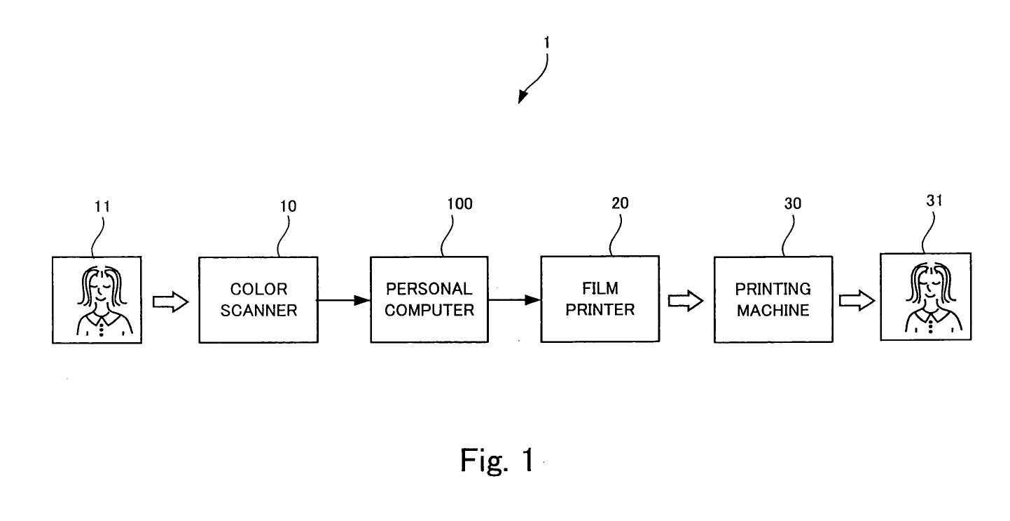

FIG. 1 is a construction view of a printing system to which an embodiment of the present invention is applied.

A printing system 1 has a printing machine 30 that permits the use of inks of the process color of CMYK 4 colors and ink of the trait of one color other than the process color. In the printing system 1, an image for printing, which is edited based on an original image 11, is printed on a sheet by the printing machine 30 to create a printed matter 31.

According to the printing system 1, as to inks of the trait in the printing machine 30, it is possible to select ink of one color from among predetermined two or more colors of inks, and further it is possible to select as to whether ink of trait is to be used or not.

Hereinafter, in order to simplify the explanation, it is assumed that trait of 0 (orange) color is used in the printing machine 30.

A color scanner 10 reads an original image 11 and creates color separation image data for RGB three colors representative of the original image 11. The image data for RGB three colors is fed to a personal computer 100. In the personal computer 100, an electronic page make-up based on the entered image data is performed by a user to create image data (it is referred to as RGB image data hereinafter) representative of an image for printing in which a color is represented by RGB three colors.

The personal computer 100 has a function that it serves as a color conversion apparatus for converting the RGB image data into image data (it is referred to as CMYKO image data hereinafter) wherein a color of an image, which is represented by the RGB image data, is represented by CMYKO five colors. This function of the personal computer 100 makes it possible to convert the RGB image data representative of the original image into the CMYKO image data.

Moreover, the personal computer 100 has a function that it serves as a so-called RIP (Raster Image Processor). This function makes it possible to convert the CMYKO image data into dot image data representative of a halftone dot image in which an image is formed with halftone dots. The conversion into the dot image data is carried out on each of CMYKO five colors, so that there is created dot image data on a form plate of the individual color of CMYKO five colors.

The dot image data is fed to a film printer 20 to create a film original plate for printing on individual form plate associated with the entered dot image data. Machine plates of individual form plates are created from the film original plates for printing, and the machine plates are mounted on the printing machine 30. Then the machine plates of individual form plates are coated with inks of colors associated with the form plates, respectively. And the coated inks are transferred to a sheet for printing. The transfer of inks is performed on the individual form plates so that the printed matter 31 is formed.

According to the color conversion from the RGB image data to the CMYKO image data, there is used a color conversion definition which defines a color conversion from the RGB color space that represents a color with RGB three colors into the CMYKO color space that represents a color with CMYKO five colors. The personal computer 100 also has a function that it serves as a color conversion definition creating apparatus of the present invention, which creates the color conversion definition as mentioned above. According to the present embodiment, the color conversion definition, which is created in the color conversion definition creating apparatus, is used in the color conversion apparatus as mentioned above to perform the color conversion.

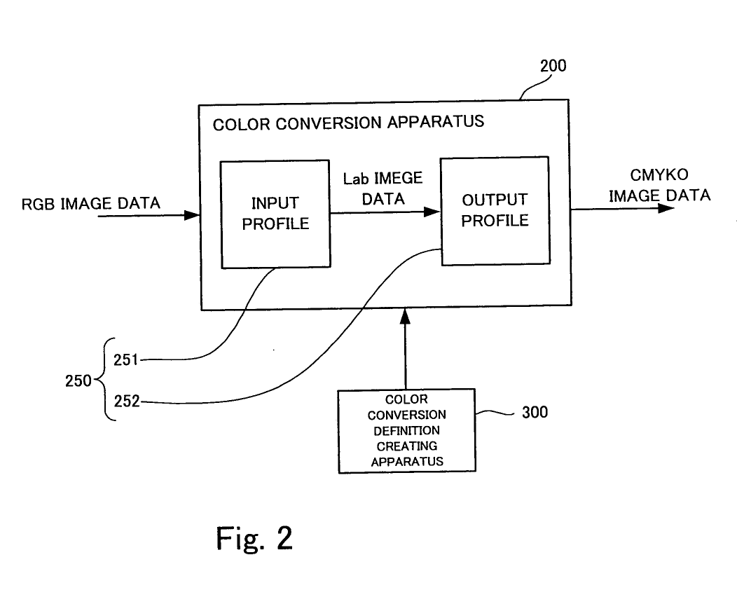

FIG. 2 is a block diagram useful for understanding a relation between a color conversion apparatus and a color conversion definition creating apparatus.

FIG. 2 typically shows a color conversion apparatus 200 that performs the color conversion from the RGB image data to the CMYKO image data, and a color conversion definition creating apparatus 300 that creates a color conversion definition 250 to be used in the color conversion.

The RGB color space depends on the equipment characteristic of the color scanner 10 in FIG. 1. The CMYKO color space depends on both the equipment characteristic of the film printer 20 and the equipment characteristic of the printing machine 30. Therefore, a color conversion apparatus 200 performs a color conversion through the Lab color space, which is an example of a common color space that is independent of the color scanner 10, the film printer 20 and the printing machine 30. According to this color conversion, the RGB image data is once converted conceptually into the Lab image data wherein a color is represented with the Lab color space, and then converted into the CMYKO image data. Hence, the color conversion definition 250 to be used for the color conversion in the color conversion apparatus 200 also performs conceptually the color conversion, as shown in FIG. 2, using both an input profile 251 that defines the color conversion from the RGB color space depending on the color scanner 10 or the input device to the Lab color space, and an output profile 252 that defines the color conversion from the Lab color space to the CMYKO color space depending on the film printer 20 and the printing machine 30 which are the output device.

The color conversion definition creating apparatus 300 creates both the input profile 251 and the output profile 252. The input profile 251 defines the color conversion between the RGB color space and the Lab color space, which are both three-dimensional color space, and is created uniquely by the already-known method. On the other hand, the output profile 252 defines the color conversion from three-dimensional color space such as the Lab color space to five-dimensional color space such as the CMYKO color space. The color conversion definition creating apparatus 300 creates the output profile 252 in such a way that the conversion relation between the three-dimension and the five-dimension, which is not essentially uniquely determined, is determined by the technique which will be described later.

The Lab color space corresponds to an example of the first color space referred to in the present invention. The CMYKO color space corresponds to an example of the second color space referred to in the present invention. The output profile 252 corresponds to an example of the color conversion definition referred to in the present invention.

Hereinafter, there will be explained the color conversion definition creating apparatus 300 particularly as to the creation of the output profile 252.

The color conversion definition creating apparatus 300 is implemented when the personal computer 100 shown in FIG. 1 operates in accordance with a color conversion definition creating program which is stored in an embodiment of the color conversion definition creating program storage medium of the present invention.

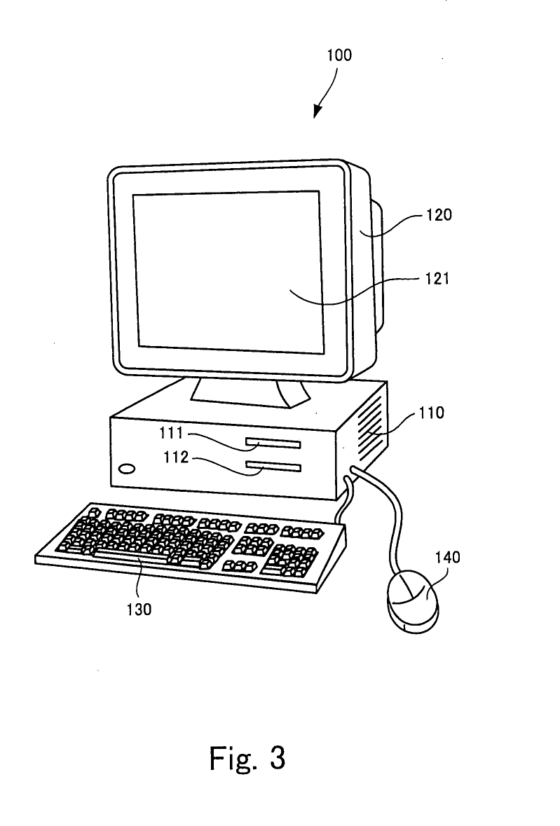

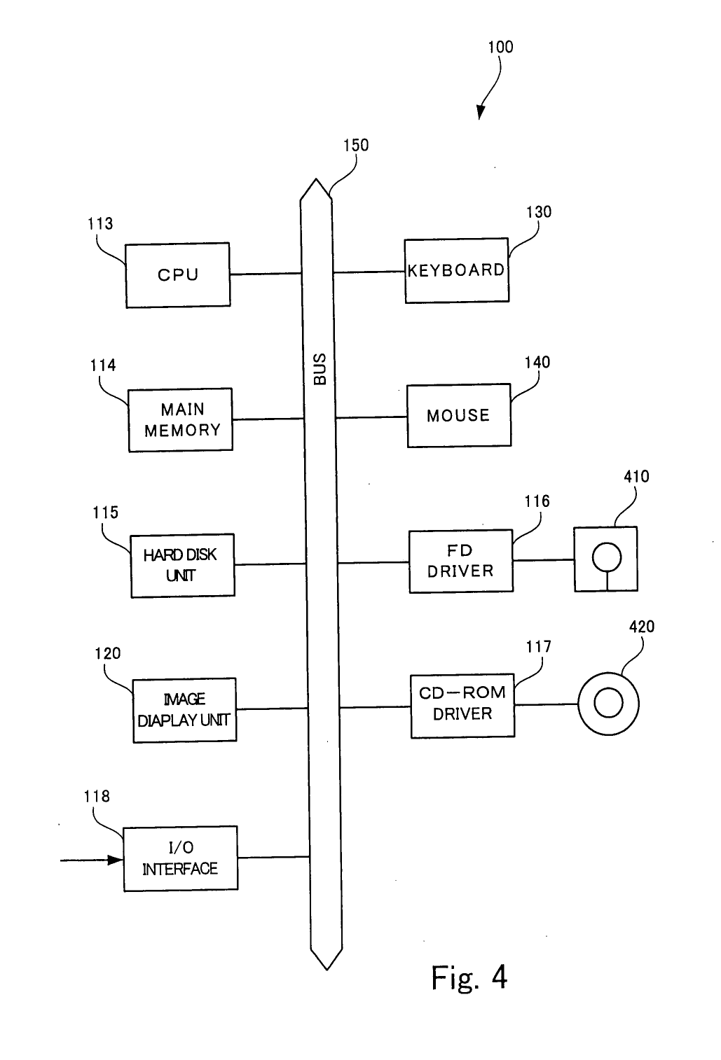

FIG. 3 is a perspective view of a personal computer 100 shown in FIG. 1. FIG. 4 is a hardware structural view of the personal computer 100 shown in FIG. 1.

The personal computer 100 comprises, on an external appearance, a main frame unit 110, an image display unit 120 for displaying an image on a display screen 121 in accordance with an instruction from the main frame unit 110, a keyboard 130 for inputting various sorts of information to the main frame unit 21 in accordance with a key operation, and a mouse 140 for inputting an instruction according to, for example, an icon and the like, through designation of an optional position on the display screen 121, the icon and the like being displayed on the position on the display screen 121. The main frame unit 110 has a flexible disk (FD) mounting slot 111 for mounting a flexible disk (FD), and a CD-ROM mounting slot 112 for mounting a CD-ROM.

The main frame unit 110 comprises, as shown in FIG. 4, a CPU 113 for executing a various types of program, a main memory 114 in which a program stored in a hard disk unit 115 is read out and developed for execution by the CPU 113, the hard disk unit 115 for saving various types of programs and data, a flexible disk drive (FD) 116 for accessing a flexible disk (FD) 410 mounted thereon, a CD-ROM drive 117 for accessing a CD-ROM 420 mounted thereon, an I/O interface 118 connected to the color scanner 10 and the film printer 20 shown in FIG. 1 to receive and transmit data between the color scanner 10 and the film printer 20. These various types of elements are connected via a bus 150 to the image display unit 120, the keyboard 130 and the mouse 150.

According to the present embodiment, the color scanner 10 and the film printer 20 stores therein an example of the color conversion definition creating program referred to in the present invention, which causes the personal computer 100 to operate as the color conversion definition creating apparatus 300 that is an embodiment of the color conversion definition creating apparatus of the present invention. When the CD-ROM 420 is mounted on the CD-ROM drive 117, the program stored in the CD-ROM 420 is up-loaded on the personal computer 100 so that the program is written into the hard disk unit 115. Thus, the personal computer 100 serves as the color conversion definition creating apparatus.

The CD-ROM 420 corresponds to an embodiment of the color conversion definition creating program storage medium of the present invention.

Hereinafter, there will be described the color conversion definition creating program and an embodiment of the color conversion definition creating program storage medium of the present invention.

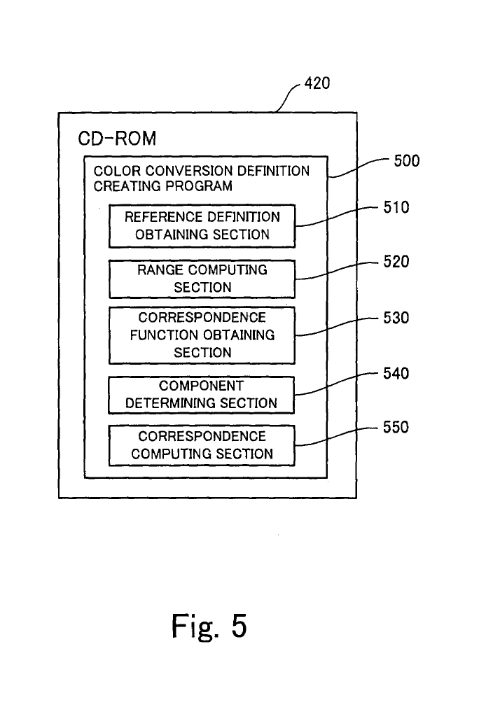

FIG. 5 is a view useful for understanding a color conversion definition creating program storage medium storing a color conversion definition creating program according to an embodiment of the present invention.

FIG. 5 typically shows the CD-ROM 420 that is an embodiment of the color conversion definition creating program storage medium of the present invention, which stores a color conversion definition creating program 500.

The color conversion definition creating program 500 causes the personal computer 100 to operate as an embodiment of the color conversion definition creating apparatus of the present invention. The color conversion definition creating program 500 comprises a reference definition obtaining section 510, a range computing section 520, a correspondence function obtaining section 530, a component determination section 540, and a correspondence computing section 550. As to details of individual elements of the color conversion definition creating program 500, it will be described later.

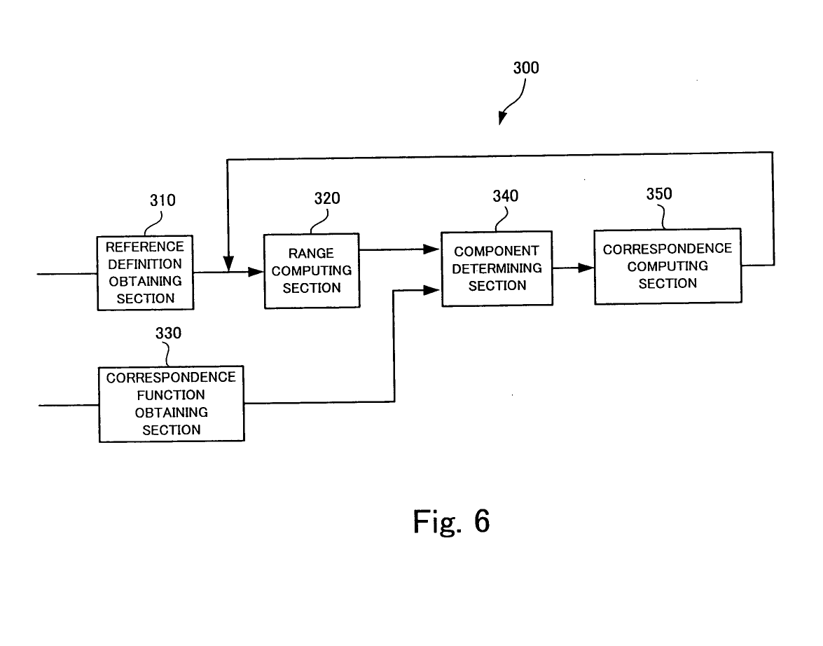

FIG. 6 is a block diagram of the color conversion definition creating apparatus according to an embodiment of the present invention, which is shown in FIG. 2 with a block.

A color conversion definition creating apparatus 300 shown in FIG. 6, which is an embodiment of the color conversion definition creating apparatus of the present invention, is implemented when the color conversion definition creating program 500 shown in FIG. 5 is installed in the personal computer 100 and is executed. The color conversion definition creating apparatus 300 comprises a reference definition obtaining section 310, a range computing section 320, a correspondence function obtaining section 330, a component determination section 340, and a correspondence computing section 350.

When the color conversion definition creating program 500 shown in FIG. 5 is installed in the personal computer 100 and is executed, the reference definition obtaining section 510, the range computing section 520, the correspondence function obtaining section 530, the component determination section 540, and the correspondence computing section 550, of the color conversion definition creating program 500 constitute the reference definition obtaining section 310, the range computing section 320, the correspondence function obtaining section 330, the component determination section 340, and the correspondence computing section 350, of the color conversion definition creating apparatus 300 shown in FIG. 6, respectively. While the respective elements of the color conversion definition creating apparatus 300 are constructed by a combination of the hardware of the personal computer and the OS and the application program executed by the personal computer, the respective elements of the color conversion definition creating program 500 shown in FIG. 5 are constructed by only the application program.

The reference definition obtaining section 310, the range computing section 320, the correspondence function obtaining section 330, the component determination section 340, and the correspondence computing section 350, of the color conversion definition creating apparatus 300, correspond to examples of the reference definition obtaining section, the range computing section, the correspondence function obtaining section, the component determination section, and the correspondence computing section, of the color conversion definition creating apparatus of the present invention, respectively.

Hereinafter, there will be explained also each element of the color conversion definition creating program 500 shown in FIG. 5 by explaining each element of the color conversion definition creating apparatus 300 shown in FIG. 6.

The reference definition obtaining section 310 obtains a CMYKO-Lab color conversion definition that defines a color conversion from the CMYKO color space to the Lab color space.

The CMYKO-Lab color conversion definition is the one that a one-to-one association between two or more lattice points which are regularly arranged on the CMYKO color space and two or more points on the Lab color space is described by the table form. The description defines the color conversion from the CMYKO color space to the Lab color space. According to the present embodiment, the CMYKO-Lab color conversion definition is created as follows. First of all, the printing machine 30 shown in FIG. 1 outputs two or more color patches that have the color corresponding to two or more prescribed representative points of two or more lattice points in the CMYKO color space. The output of the color patches is carried out in accordance with patch data in which colors of individual color patches are represented by coordinates (C value, M value, Y value, K value, O value: dot percent values of individual colors of CMYKO) of individual representative points in the CMYKO color space. Colors of the individual color patches thus outputted are measured to obtain calorimetric values (Lab values) of the individual color patches. Next, with respect to the lattice points other than the above-mentioned representative points in the CMYKO color space, the associated Lab values are computed in accordance with the interpolation processing using the colorimetric values. And finally, a table, which associates the CMYKO values of the whole lattice points with the Lab values, is created, so that the CMYKO-Lab color conversion definition is completed. The CMYKO-Lab color conversion definition corresponds to an example of the reference definition referred to in the present invention.

According to the present embodiment, there is created the output profile 252 (cf. FIG. 2) that defines the color conversion from the Lab color space to the CMYKO color space, which is opposite to the color conversion defined by the CMYKO-Lab color conversion definition that is obtained in the reference definition obtaining section 310, in accordance with the CMYKO-Lab color conversion definition. The output profile 252 is the one that a one-to-one association between two or more lattice points which are regularly arranged on the Lab color space and two or more points on the CMYKO color space is described by the table form. It seems to be able to calculate the association between individual lattice points on the Lab color space and individual points on the CMYKO color space by reversely referring simply seemingly to the above-mentioned CMYKO-Lab color conversion definition. However, coordinates of the five-dimensional color space corresponding to coordinates of the three-dimensional color space are not obtained mathematical and uniquely. Therefore, according to the present embodiment, the association between individual lattice points on the Lab color space and individual points on the CMYKO color space is determined as follows, referring to the CMYKO-Lab color conversion definition.

First of all, the range computing section 320 and the component determination section 340 determine K values and O values in the CMYKO color space with respect to individual lattice points on the Lab color space. According to the present embodiment, first of all, K value that it is easy to be recognized to man's eyes and the influence that it has an effect on the accuracy of the color conversion is large is previously decided, and 0 value is decided by using the decided K value. As a result, the improvement of the accuracy of the color conversion definition is attempted.

Hereinafter, there will be described determination of the K value.

The range computing section 320 sets one of two or more lattice points on the Lab color space to a starting coordinate in accordance with a predetermined priority. Then the range computing section 320 computes, as to K value, a component range in which the mapping is permitted onto the starting coordinate by the color conversion according to the CMYKO-Lab color conversion definition.

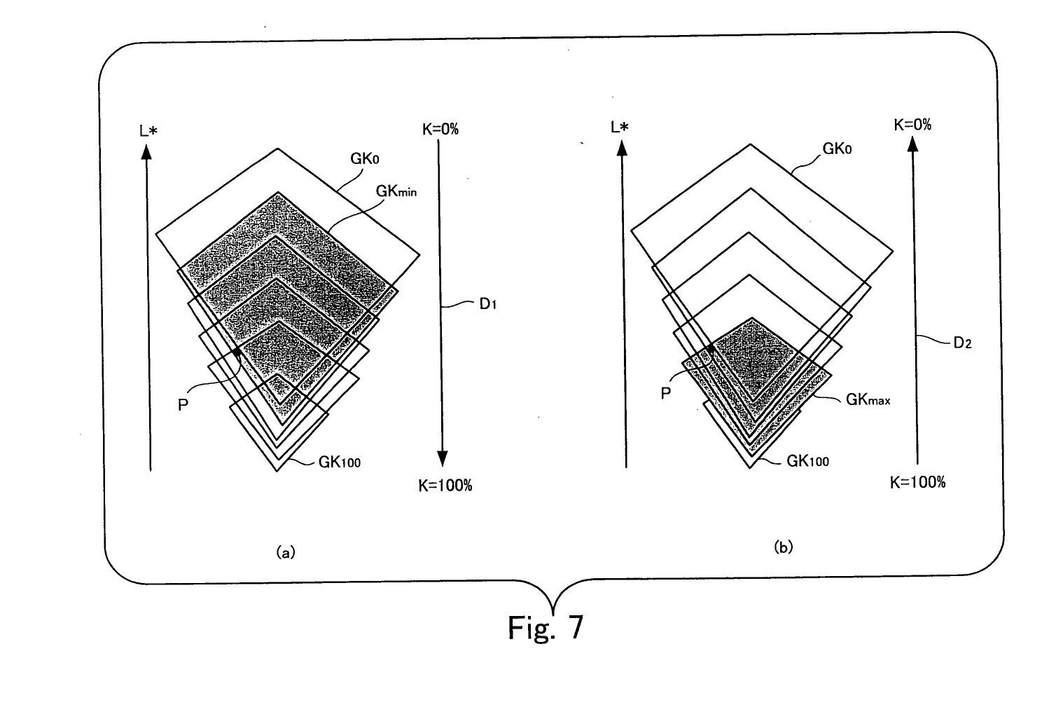

FIG. 7 is a view useful for understanding a state that a component range of K value, in which a mapping can be made at a certain starting coordinate, is computed.

A part (a) of FIG. 7 shows the state in which the lower limit (lower limit value Kₘᵢₙ of K) in the component range of K value. A part (b) of FIG. 7 shows the state in which the upper limit (upper limit value Kₘₐₓ of K) in the component range of K value.

Hereinafter, there will be explained the computation of the lower limit value Kₘᵢₙ of K. According to this computation, the range computing section 320 computes first a range (gamut) GK₀ of color capable of being outputted in the printing system 1 shown in FIG. 1 on the Lab color space, in the state that K value is fixed to 0%, in the manner as set fourth below.

Coordinates on the Lab color space, which have a one-to-one correspondence with coordinates that are obtained when C value, M value, Y value, K value, O value are varied between 0% and 100% at regular intervals in the state that K value is fixed to 0%, are computed in accordance with the CMYKO-Lab color conversion definition. The range enclosed with coordinates located on the outside edge on the Lab color space is made gamut GK₀ corresponding to K value=0% among the calculated coordinates. The part (a) of FIG. 7 shows the gamut GK₀ with its section where the gamut GK₀ is cut by a parallel plane to L* axis. Moreover, though L* axis is also shown in the part (a) of FIG. 7, to make the figure easy to see, the gamut GK₀ originally located on the L* axis is shown at the right of the L* axis in the part (a) of FIG. 7. Thus, when the gamut GK₀ corresponding to K value=0% is determined, the range computing section 320 then decides whether the gamut GK₀ includes the starting coordinate P which is one of the lattice points on the Lab color space. In the event that the range computing section 320 then decides that the gamut GK₀ includes the starting coordinate P, the value of 0% is set to the lower limit value Kₘᵢₙ of K. On the other hand, in the event that the range computing section 320 decides that the gamut GK₀ does not include the starting coordinate P, the K value is increased by a predetermined amount, and the range computing section 320 performs, as to the increased K value, the computation of the gamut and the decision of the starting coordinate P as mentioned above. As the K value is increased in the manner as mentioned above, as seen from the part (a) of FIG. 7, the gamut varies in such a way that the gamut goes down along the L* axis from the gamut GK₀ at K value=0% to the gamut GK₁₀₀ at K value=100%, and narrows in width. The range computing section 320 performs the computation of the gamut and the decision processing as mentioned above, while the K value is increased from 0% to 100%, as an arrow D₁ shows. The change of K value is stopped when judged that the starting coordinate P is included in the gamut, like gamut GKₘᵢₙ in which hatching is done in the figure, and K value at that time is decided to be the lower limit value Kₘᵢₙ of K to the starting coordinate P.

Next, there will be explained the upper limit value Kₘₐₓ of K. According to this computation, the range computing section 320 performs the computation of the gamut and the decision processing as mentioned above, while the K value is decreased from 100% to 0%, as an arrow D₂ shows. As the K value is decreased in the manner as mentioned above, as seen from the part (b) of FIG. 7, the gamut varies in such a way that the gamut goes up along the L* axis from the gamut GK₁₀₀ at K value=100% to the gamut GK₀ at k value=0%, and spreads in width. The change of K value is stopped when judged that the starting coordinate P is included in the gamut, like gamut GKₘₐₓ in which hatching is done in the figure, and K value at that time is decided to be the upper limit value Kₘₐₓ of to the starting coordinate P.

Thus, when the component range of K value, in which a mapping can be made at a certain starting coordinate, is decided, the component determination section 340 shown in FIG. 6 decides the K value corresponding to the starting coordinate P to the coordinate component within the component range in accordance with the following expression.

K value=W_{K}×upper limit value Kₘₐₓ of K+(1−W_{K})×lower limit value Kₘᵢₙ of K

where “W_{K}” is a coefficient (weight) indicative of how much the K value is biased to the upper limit value Kₘₐₓ side between the upper limit value Kₘₐₓ of K and the lower limit value Kₘᵢₙ of K. The coefficient “W_{K}” is expressed by the product of weight function W_{KL} in which the variable is L* value corresponding to brightness of the Lab values representative of the starting coordinate P, and weight function W_{KC} in which the variable is chroma saturation C represented by (a*²+b*²)^{1/2}.

According to the present embodiment, the formula of the weight W_{K} consisting of the product of two kinds of weight functions is previously created by a user and stored in a memory (not illustrated). The correspondence function obtaining section 330 shown in FIG. 6 reads the formula of the weight W_{K} from the memory (not illustrated). The formula of the weight W_{K} corresponds to an example of the correspondence function referred to in the present invention.

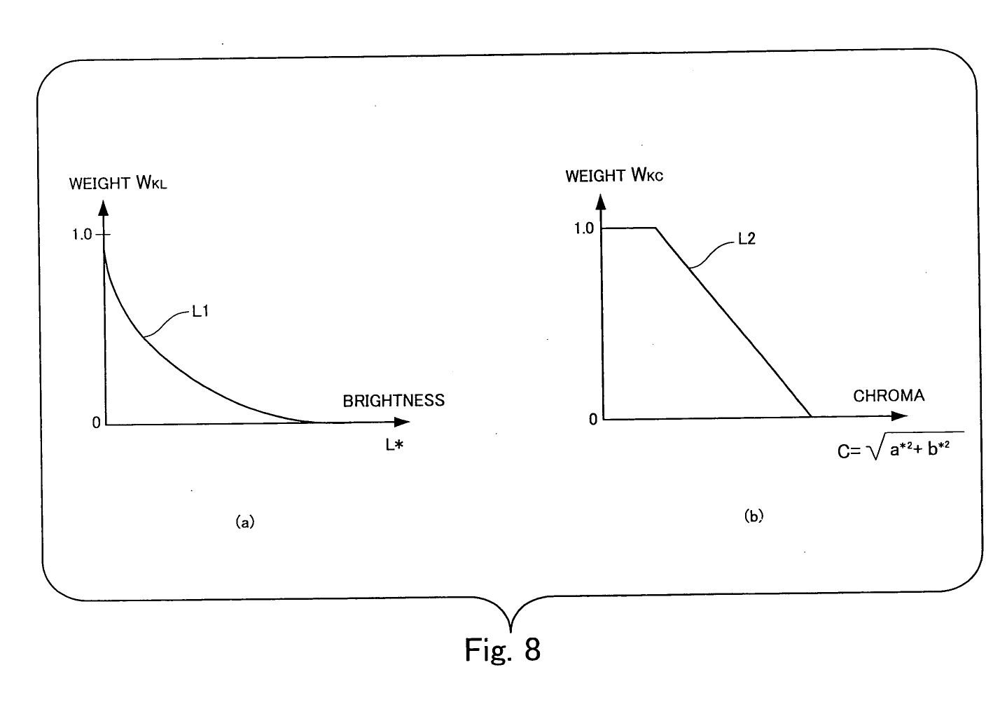

FIG. 8 is a view showing an example of weight function W_{KL} of L* value and an example of weight function W_{KC} of chroma saturation C.

A part (a) of FIG. 8 shows a line L1 representative of the weight function W_{KL} of L* value. A part (b) of FIG. 8 shows a line L2 representative of the weight function W_{KC} of chroma saturation C.

According to the example of FIG. 8, as seen from the line L1 of the part (a) of FIG. 8, the weight function W_{KL} of L* value is a function that weight decreases as brightness rises. And as seen from the line L2 of the part (b) of FIG. 8, the weight function W_{KC} of chroma saturation C is a function that it becomes the weight of “1.0” in a prescribed low chroma area and weight decreases on the high chroma side as the chroma rises.

The weight W_{K} represented by product of two kinds of weighting functions W_{KL} and W_{K} c determines K value in such a manner that the K value is decided to a lot of coordinates elements in which the K value is close to the upper limit value Kₘₐₓ in the above-mentioned range, with respect to the lattice point on the shadow side where brightness and the chroma are for instance low, and it is decided to few coordinates elements in which the K value is close to the lower limit value Kₘᵢₙ in the above-mentioned range, with respect to the lattice point that is bright and vivid in color.

Thus, when the K value on a certain starting coordinate is decided in accordance with the procedure explained in conjunction with FIG. 7 and FIG. 8, the range computing section 320 and the component determination section 340 execute the decision of an O value associated with the trait in accordance with the technique similar to the decision of the K value in the manner as set fourth below.

Also in the decision of O value, in a similar fashion to the decision of the K value as mentioned above, first, the component range of O value, in which a mapping can be made at a certain starting coordinate, is computed. At that time, the K value is fixed to the coordinate component that is determined by the above mentioned procedure.

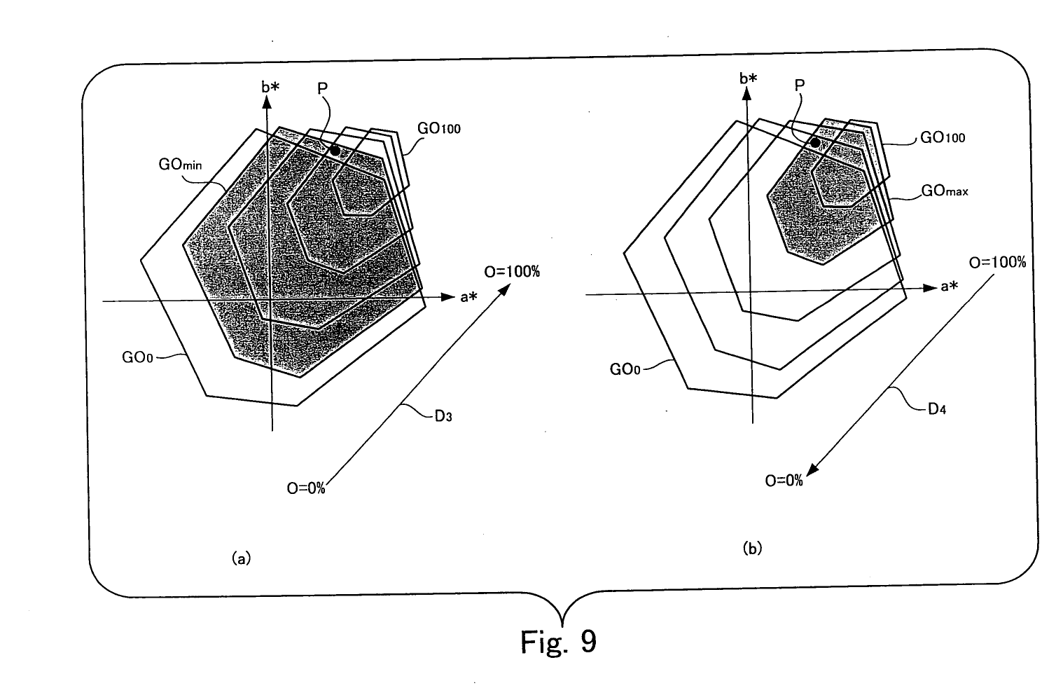

FIG. 9 is a view useful for understanding a state that a component range of O value, in which a mapping can be made at a certain starting coordinate, is computed.

A part (a) of FIG. 9 shows the state in which the lower limit (lower limit value Oₘᵢₙ of O) in the component range of O value. A part (b) of FIG. 9 shows the state in which the upper limit (upper limit value Oₘₐₓ of O) in the component range of O value.

According to the computation of the lower limit value Oₘᵢₙ of O, the range computing section 320 executes the computation of the gamut and the decision processing as mentioned above, in the state that K value is fixed, while the O value is increased from 0% to 100%, as an arrow D₃ shows in the part (a) of FIG. 9. The gamut is changed as it goes away from coordinates of a*=b*=0 and the area narrows as the O value increases. The part (a) of FIG. 9 shows the change of the gamut with its section where the gamut is cut by a parallel plane to a*b* plane. The range computing section 320 stops the change of the O value from gamut GO₀ at the O value=0% to gamut GO₁₀₀ at the O value=100%, when judged that the starting coordinate P is included in the gamut, like gamut GOₘᵢₙ in which hatching is done in the figure, and O value at that time is decided to be the lower limit value Oₘᵢₙ of O to the starting coordinate P.

According to the computation of the upper limit value Oₘₐₓ of O, the range computing section 320 executes the computation of the gamut and the decision processing as mentioned above, while the O value is decreased from 100% to 0%, as an arrow D₄ shows in the part (b) of FIG. 9. When the O value is changed, as shown in the part (b) of FIG. 9, the gamut is changed in such a way that the area spreads from gamut GO₁₀₀ at the O value=100% to gamut GO₀ at the O value=0%. The range computing section 320 stops the change of the O value, when judged that the starting coordinate P is included in the gamut, like gamut GOₘₐₓ in which hatching is done in the figure, and O value at that time is decided to be the upper limit value Oₘₐₓ of O to the starting coordinate P.

Thus, when the component range of O value, in which a mapping can be made at a certain starting coordinate, is decided, the component determination section 340 shown in FIG. 6 decides the O value corresponding to the starting coordinate P to the coordinate component within the component range in accordance with the following expression.

O value=W₀×upper limit value Oₘₐₓ of O+(1−Wₒ)×lower limit value Oₘᵢₙ of O

where “W_{O}” is a coefficient (weight) indicative of how much the O value is biased to the upper limit value Oₘₐₓ side between the upper limit value Oₘₐₓ of O and the lower limit value Oₘᵢₙ of O. The coefficient “W_{O}” is expressed by the product of weight function W_{OH} in which the variable is tan⁻¹ (b*/a*) color phase angle H, and weight function W_{OC} in which the variable is chroma saturation C. The formula of the weight W_{O}of the O value also corresponds to an example of the correspondence function referred to in the present invention. The formula of the weight W_{O} is previously created by a user and stored in a memory (not illustrated). The correspondence function obtaining section 330 shown in FIG. 6 reads the formula of the weight W_{O} from the memory (not illustrated). According to the present invention, it is assumed that the weight W_{O} of the O value is constant with “1. 0” for the L* value of the Lab values representative of the starting coordinate P. The formula of the weight W_{O} is expressed by the product of two weight functions W_{OH} and W_{OC} represented by a* value and b* value as mentioned above.

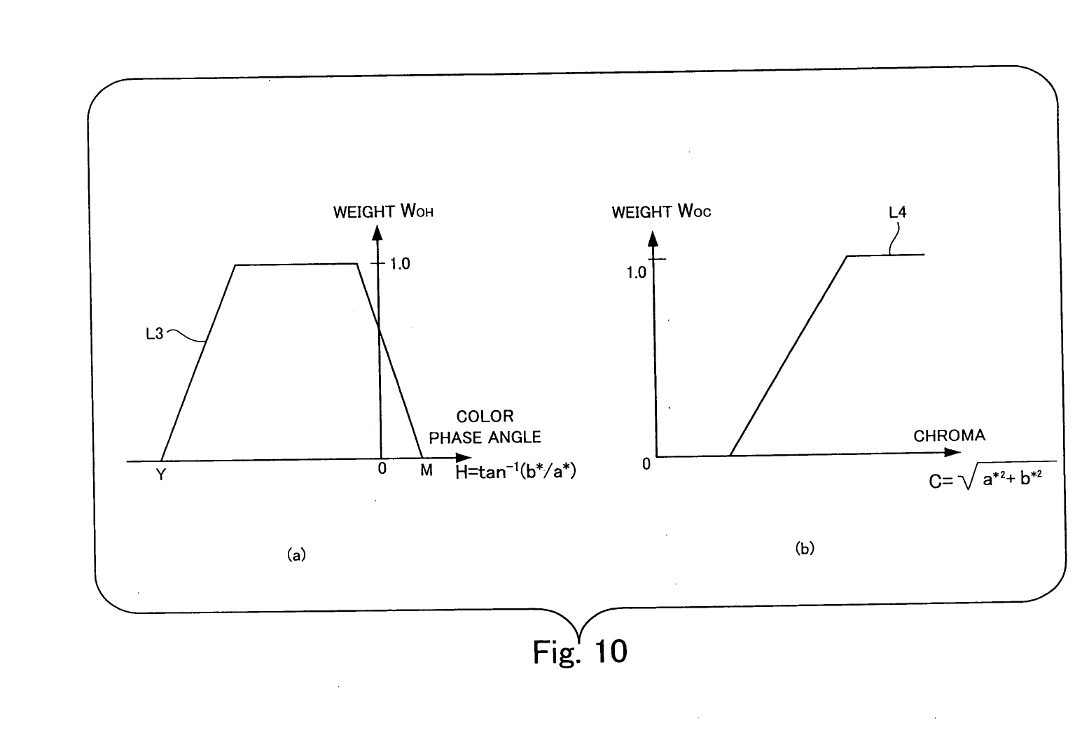

FIG. 10 is a view showing an example of weight function W_{OH} of color-phase angle H and an example of weight function W_{OC} of chroma saturation C.

A part (a) of FIG. 10 shows a line L3 representative of the weight function W_{OH} of color-phase angle H. A part (b) of FIG. 10 shows a line L4 representative of the weight function W_{OC} of chroma saturation C.

According to the example of FIG. 10, as seen from the line L3 of the part (a) of FIG. 10, the weight function W_{OH} of color-phase angle H is a function that it offers weight of “1.0” within a predetermined color-phase range in the vicinity of O color halfway between Y color and M color, and weight decreases as it goes apart from the color-phase range. And as seen from the line L4 of the part (b) of FIG. 10, the weight function W_{OC} of chroma saturation C is a function that it becomes the weight of “0” in a prescribed low chroma area, and when the chroma saturation C exceeds a predetermined value, weight increases and it becomes the weight of “1.0” in a prescribed high chroma area.

The weight W_{O} determines O value in such a manner that the O value is decided to a lot of values in which the O value is close to the upper limit value Oₘₐₓ in the above-mentioned range, with respect to the lattice point in the vicinity of O color for instance, the O value is decided to “0”, with respect to the lattice point in the vicinity of gray color, and the O value is decided to a lot of values in which the O value is close to the upper limit value Oₘₐₓ in the above-mentioned range, with respect to the lattice point that is bright and vivid in color.

Thus, the K value and the O value on a certain starting coordinate are decided in accordance with the procedure explained in conjunction with FIG. 7 to FIG. 10.

Next, the correspondence computing section 350 determines C value, M value and Y value, which are the remaining three components in the CMYKO color space, with respect to the starting coordinate. Those three coordinate components are mathematically and uniquely computed from the above mentioned CMYKO-Lab color conversion definition when the K value and the O value are fixed on the coordinate components determined by the component determination section 340, respectively. This computing method is well known, and the detailed explanation will be omitted.

Thus, when one of two or more lattice points in the Lab color space is assumed to be the starting coordinate, and coordinates of the CMYKO color space corresponding to the lattice point are computed, the range computing section 320 decides the subsequent lattice point to the starting coordinate in accordance with a prescribed priority level. The above-mentioned procedure is repeated to compute the coordinates of the CMYKO color space corresponding to the lattice point. According to the present embodiment, when the above-mentioned processing is carried out on individual one of two or more lattice points, there are determined one-to-one correspondences between two or more lattice points in the Lab color space and two or more coordinates in the CMYKO color space. The thus determined correspondences are described in form of a table, so that the output profile 252 is created.

As mentioned above, according to the color conversion definition creating apparatus 300 of the present embodiment, a creation of the output profile 252 for defining a color conversion from a three-dimensional color space of the Lab color space to a five-dimensional color space of the CMYKO color space is performed in accordance with such a procedure that first, K values and O values associated with individual lattice points in the Lab color space are determined, and then the remaining CMY three values are determined. At that time, K values and O values are determined to coordinate components within a component range in which mapping can be made at individual lattice points. As a result, it is possible to avoid such a trouble that K value and O value, in which the color that each lattice point represents is not expressible, lower the accuracy of the color conversion. To determine K value and O value, a coordinate component of the Lab color space and the chroma saturation and the color phase angle determined from the coordinate component are assumed to be a variable, and a weight function continuously associated with coordinates of the Lab color space is used. The use of such a weight function makes it possible that K values and O values are decided to suitable values within the above-mentioned component range. Thus, it is possible to avoid jump and the tone jump of an unnatural color in the color conversion. In other words, according to the color conversion definition creating apparatus 300 of the present embodiment, it is possible to create the color conversion definition that defines the color conversion from the three-dimensional color space to the four or more-dimensional color space with great accuracy.

In the above description, as an embodiment of the color conversion definition creating apparatus of the present invention, there is disclosed the color conversion definition creating apparatus 300 for creating the color conversion definition that defines the color conversion from the Lab color space to the CMYKO color space. According to the present embodiment, the color conversion definition creating apparatus is associated with the printing machine 30 (cf. FIG. 1) that permits the use of inks of the process color of CMYK 4 colors and ink of the trait of one color other than the process color. It is noted, however, that the color conversion definition creating apparatus of the present invention is not restricted to such a type associated with the printing machine 30 as mentioned above, and it is acceptable that the color conversion definition creating apparatus of the present invention is for example one which is associated with a color monitor for display colors with reference colors of RGB three colors and supplementary colors other than the reference colors.

Hereinafter, regarding an embodiment which is associated with such a color monitor, there will be explained the embodiment particularly the feature part. Here, it is assumed that C color is used as a supplementary color in the above-mentioned color monitor.

According to the color conversion definition creating apparatus of the present embodiment, there is created an output profile that defines the color conversion from the Lab color space to the CMYKO color space. In the creation of the output profile, first, there is prepared RGBC-Lab color conversion definition (it corresponds to an example of the reference definition referred to in the present invention) which defines the color conversion from the RGBC color space to the Lab color space. Then, one of two or more lattice points, which are regularly arranged in the Lab color space, is decided to the starting coordinate in accordance with a prescribed priority level. First, with respect to C value, a component range of the C value, in which a mapping can be made at the starting coordinate, is computed by the color conversion according to the CMYKO-Lab color conversion definition.

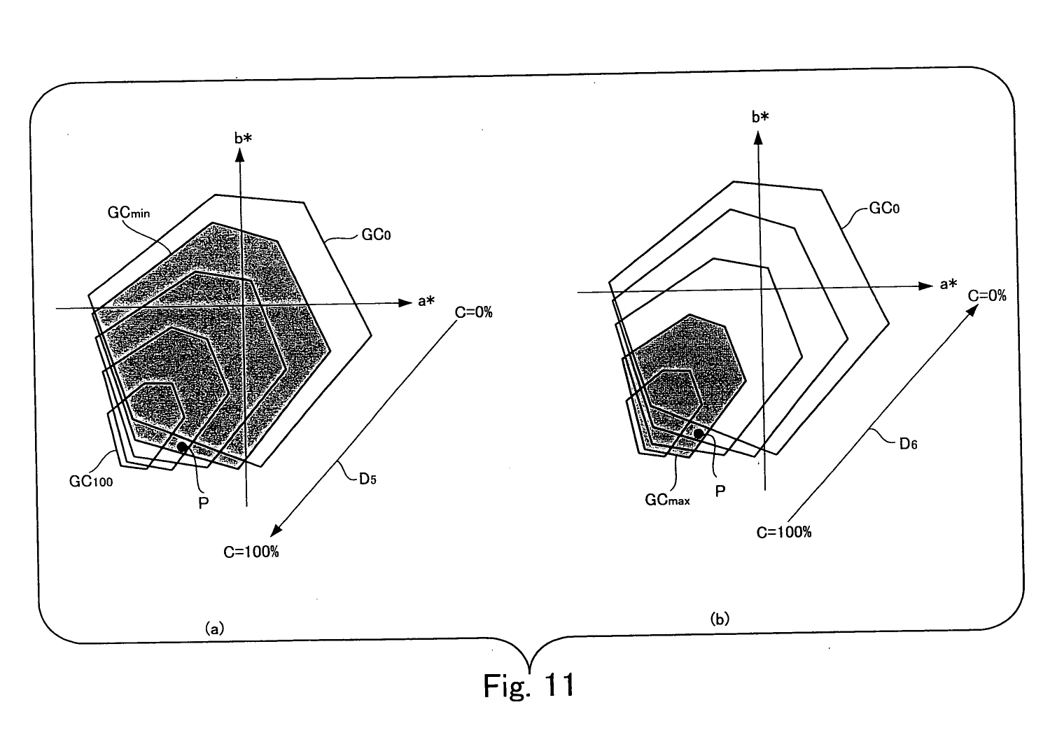

FIG. 11 is a view useful for understanding a state that a component range of C value, in which a mapping can be made at a certain starting coordinate, is computed.

A part (a) of FIG. 11 shows the state in which the lower limit (lower limit value Cₘᵢₙ of C) in the component range of C value. A part (b) of FIG. 11 shows the state in which the upper limit (upper limit value Cₘₐₓ of C) in the component range of C value.

According to the computation of the lower limit value Cₘᵢₙ of C, the range computing section 320 executes the computation of the gamut associated with individual C value and the decision processing as to whether the computed gamut includes the starting coordinate P, while the C value is sequentially increased from 0% to 100%, as an arrow D₅ shows in the part (a) of FIG. 11. The gamut is changed as it goes away from coordinates of a*=b*=0 and the area narrows as the C value increases. The part (a) of FIG. 11 shows the change of the gamut with its section where the gamut is cut by a parallel plane to a*b* plane. The range computing section 320 stops the change of the C value from gamut GC₀ at the C value=0% to gamut GC₁₀₀ at the C value=100%, when judged that the starting coordinate P is included in the gamut, like gamut GCₘᵢₙ in which hatching is done in the figure, and C value at that time is decided to be the lower limit value Cₘᵢₙ of C to the starting coordinate P.

According to the computation of the upper limit value Cₘₐₓ of C, the range computing section 320 executes the computation of the gamut associated with individual C value and the decision processing as mentioned above, while the C value is sequentially decreased from 100% to 0%, as an arrow D₆ shows in the part (b) of FIG. 11. When the C value is changed, as shown in the part (b) of FIG. 11, the gamut is changed in such a way that the area spreads from gamut GC₁₀₀ at the C value=100% to gamut GO₀ at the O value=0%. The range computing section 320 stops the change of the C value, when judged that the starting coordinate P is included in the gamut, like gamut GCₘₐₓ in which hatching is done in the figure, and C value at that time is decided to be the upper limit value Cₘₐₓ of C to the starting coordinate P.

Thus, when the component range of C value is decided, the component determination section 340 shown in FIG. 6 decides the C value corresponding to the starting coordinate P to the coordinate component within the component range in accordance with the following expression.

C value=W_{c}×upper limit value Cₘₐₓ of C+(1−W_{C})×lower limit value Cₘᵢₙ of C

where “W_{C}” is a coefficient (weight) indicative of how much the C value is biased to the upper limit value Cₘₐₓ side between the upper limit value Cₘₐₓ of C and the lower limit value Cₘᵢₙ of C. The coefficient “W_{C}” is expressed by the product of weight function W_{CH} in which the variable is tan⁻¹ (b*/a*) color phase angle H, and weight function W_{CC} in which the variable is chroma saturation C. The formula of the weight W_{C} of the C value corresponds to an example of the correspondence function referred to in the present invention. According to the present invention, it is assumed that the weight W_{C} of the C value is constant with “1.0” for the L* value of the Lab values representative of the starting coordinate P. The formula of the weight W_{C} is expressed by the product of two weight functions W_{CH} and W_{CC} represented by a* value and b* value as mentioned above.

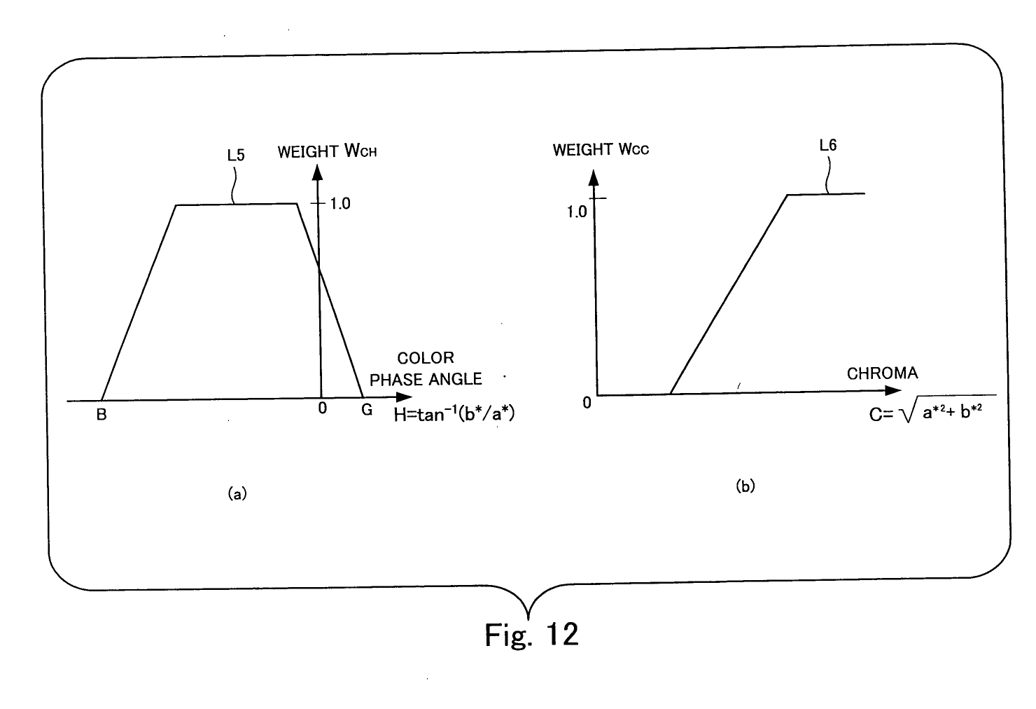

FIG. 12 is a view showing an example of weight function W_{CH} of color-phase angle H and an example of weight function W_{CC} of chroma saturation C.

A part (a) of FIG. 12 shows a line L5 representative of the weight function W_{CH} of color-phase angle H. A part (b) of FIG. 12 shows a line L6 representative of the weight function W_{CC} of chroma saturation C.

According to the example of FIG. 12, as seen from the line L5 of the part (a) of FIG. 12, the weight function W_{CH} of color-phase angle H is a function that it offers weight of “1.0” within a predetermined color-phase range in the vicinity of C color halfway between B color and G color, and weight decreases as it goes apart from the color-phase range. And as seen from the line L6 of the part (b) of FIG. 12, the weight function W_{CC} of chroma saturation C is a function that it becomes the weight of “0” in a prescribed low chroma area, and when the chroma saturation C exceeds a predetermined value, weight increases and it becomes the weight of “1.0∞ in a prescribed high chroma area.

The weight W_{C} determines C value in such a manner that the C value is decided to a lot of values in which the C value is close to the upper limit value Cₘₐₓ in the above-mentioned range, with respect to the lattice point in the vicinity of C color for instance, the C value is decided to “0”, with respect to the lattice point in the vicinity of gray color, and the C value is decided to a lot of values in which the C value is close to the upper limit value Cₘₐₓ in the above-mentioned range, with respect to the lattice point that is bright and vivid in color.

Thus, when the coordinate component of the C value is decided, the coordinate components of RGB three colors associated with the starting coordinate are computed in accordance with the RGBC-Lab color conversion definition. The above-mentioned computation is carried out on individual two or more lattice points in the Lab color space and there is created the output profile that defines the color conversion from the Lab color space to the RGBC color space.

In a similar fashion to that of the color conversion definition creating apparatus 300 (cf. FIG. 6) according to the embodiment which is associated with the printing machine 30 (cf. FIG. 1), it is possible to create the color conversion definition that defines the color conversion from the three-dimensional color space to the four-dimensional color space with great accuracy also by the color conversion definition creating apparatus according to the embodiment which is associated with the color monitor.

According to the present embodiments, by way of the examples of the color conversion definition creating apparatus referred to in the present invention, there are disclosed the color conversion definition creating apparatus that creates the color conversion definition from the three-dimensional color space to the four-dimensional color space, and the color conversion definition creating apparatus that creates the color conversion definition from the three-dimensional color space to the five-dimensional color space. However, the present invention is not restricted to those embodiments. According to the present invention, it is acceptable that the color conversion definition creating apparatus referred to in the present invention is, for example, a color conversion definition creating apparatus that creates the color conversion definition from the three-dimensional color space to the six or more-dimensional color space.

Further, according to the present embodiments, by way of the example of the common color space, there is shown the Lab color space. However, the present invention is not restricted to those embodiments. According to the present invention, it is acceptable that the common color space is XYZ space, or alternatively sRGB color space.

According to the present embodiments, by way of the examples of the color conversion definition referred to in the present invention, there is disclosed the output profile 252 in which it is assumed that device non-dependence common color space is the output side of color space. However, the present invention is not restricted to those embodiments. According to the present invention, it is acceptable that the color conversion definition of the present invention is one in which it is-assumed that device dependence RGB color space and CYM space etc. are an output side of color space for instance.

According to the present embodiments, by way of the examples of the correspondence function obtaining section referred to in the present invention, there is disclosed the correspondence function obtaining section 330 that reads the product of two sorts of weight functions from a memory (not illustrated). However, the present invention is not restricted to those embodiments. According to the present invention, it is acceptable that the correspondence function obtaining section referred to in the present invention is one in which the product of two sorts of weight functions are obtained by user's operation and the like for instance.

According to the present embodiments, by way of the examples of the correspondence function referred to in the present invention, there is disclosed the product of two sorts of weight functions. However, the present invention is not restricted to those embodiments. According to the present invention, it is acceptable that the correspondence function referred to in the present invention is, for instance, one sort of weight function, or three or more sorts of weight functions.

As mentioned above, according to the present invention, it is possible to provide a color conversion definition creating apparatus capable of creating a color conversion definition that defines a color conversion from a three-dimensional color space to a four or more-dimensional color space with greater accuracy, and a color conversion definition creating program storage medium storing a color conversion definition creating program which causes a computer to operate as such a color conversion definition creating apparatus, when the color conversion definition creating program is incorporated into the computer and is executed.

While the present invention has been described with reference to the particular illustrative embodiments, it is not to be restricted by those embodiments but only by the appended claims. It is to be appreciated that those skilled in the art can change or modify the embodiments without departing from the scope and sprit of the present invention.

What is claimed is:

1. A color conversion definition creating apparatus for creating a color conversion definition that defines a color conversion from a first color space having three coordinate axes to a second color space having four or more coordinate axes, the conversion definition creating apparatus comprising:
a reference definition obtaining section that obtains a reference definition defining a color conversion from the second color space to the first color space;
a range computing section that determines a starting coordinate on the first color space, and computes, as to coordinate components of coordinate axes other than three predetermined coordinate axes among the coordinate axes of the second color space, a component range in which mapping is permitted onto the starting coordinate by the color conversion according to the reference conversion definition;
a correspondence function obtaining section that obtains correspondence functions in which relative positions of the coordinate components within the component range are associated with individual coordinates on the first color space;
a component determination section that determines coordinate components associated with the starting coordinate in accordance with the component range computed by the range computing section and the correspondence function obtained by the correspondence function obtaining section; and
a correspondence computing section that computes individual coordinate components of said three predetermined coordinate axes in accordance with the starting coordinate, the coordinate components determined by the component determination section, and the reference definition obtained by the reference definition obtaining section, so that coordinates of the second color space associated with the starting coordinate are obtained.

2. A color conversion definition creating apparatus according to claim 1 wherein the first color space is a color space in which a color is represented by a calorimetric value.

3. A color conversion definition creating apparatus according to claim 1 wherein the second color space is a color space having the coordinate axes associated with four or more color elements, respectively, which represents a color that is expressed by those color elements.

4. A color conversion definition creating apparatus according to claim 1 wherein the second color space is five or more dimensional color space,
the component determination section determines coordinate components one by one on individual coordinate axes other than three predetermined coordinate axes, and
the range computing section computes, as to coordinate axes that are not yet decided in coordinate component, the component range under condition that as to coordinate axes that are already decided in coordinate component, the coordinate component is used on a fixing basis.

5. A color conversion definition creating apparatus according to claim 1 wherein the second color space is a color space having the coordinate axes associated with four or more color elements including K color, respectively, which represents a color that is expressed by those color elements, and
the range computing section and the component determination section execute computation of the component range and determination of the coordinate components as to coordinate axis associated with K color first, respectively.

6. A color conversion definition creating apparatus according to claim 1 wherein the second color space is a color space having the coordinate axes associated with five or more color elements including CMY three colors, K color, and one or more traits, respectively, which represents a color that is expressed by those color elements,
the range computing section and the component determination section execute computation of the component range and determination of the coordinate components as to coordinate axis associated with K color first, respectively, and then execute computation of the component range and determination of the coordinate components as to coordinate axes associated with individual traits, sequentially, respectively, and
the correspondence computing section computes coordinate components as to individual coordinate axes associated with CMY three colors, respectively.

7. A color conversion definition creating program storage medium storing a color conversion definition creating program which causes a computer to operate as a color conversion definition creating apparatus, when the color conversion definition creating program is incorporated into the computer and is executed, the color conversion definition creating apparatus creating a color conversion definition that defines a color conversion from a first color space having three coordinate axes to a second color space having four or more coordinate axes, the conversion definition creating apparatus comprising:
a reference definition obtaining section that obtains a reference definition defining a color conversion from the second color space to the first color space;
a range computing section that determines a starting coordinate on the first color space, and computes, as to coordinate components of coordinate axes other than three predetermined coordinate axes among the coordinate axes of the second color space, a component range in which mapping is permitted onto the starting coordinate by the color conversion according to the reference conversion definition;
a correspondence function obtaining section that obtains correspondence functions in which relative positions of the coordinate components within the component range are associated with individual coordinates on the first color space;
a component determination section that determines coordinate components associated with the starting coordinate in accordance with the component range computed by the range computing section and the correspondence function obtained by the correspondence function obtaining section; and
a correspondence computing section that computes individual coordinate components of said three predetermined coordinate axes in accordance with the starting coordinate, the coordinate components determined by the component determination section, and the reference definition obtained by the reference definition obtaining section, so that coordinates of the second color space associated with the starting coordinate are obtained.
